(19) United States
(12) Patent Application Publication
(10) Pub. No.: US 2025/0212357 A1
(43) Pub. Date: Jun. 26, 2025

(54) METHODS AND APPARATUS TO CONTROL AIRFLOW IN FOLDABLE COMPUTING DEVICES

(71) Applicant: Intel Corporation, Santa Clara, CA (US)

(72) Inventors: Snehal Chaudhari, Bangalore (IN); Arnab Sen, Bangalore (IN); Samarth Alva, Bangalore (IN); Ravishankar Srikanth, Bangalore (IN); Bharath Kumar K, Bangalore (IN); Jeff Ku, Taipei (TW); Shreedhar Shahapur, Bangalore (IN); Sandhya Gupta, Bangalore (IN); Ravi Kumar, Bangalore (IN); Vipin Bokade, Bangalore (IN)

(21) Appl. No.: 18/393,250

(22) Filed: Dec. 21, 2023

(51) Int. Cl. H05K 7/20; G06F 1/16

(52) U.S. Cl. CPC H05K 7/20145; G06F 1/1616; G06F 1/1681

(57) ABSTRACT

Methods and apparatus to control airflow in foldable computing devices are disclosed. A disclosed apparatus for use with a foldable computing device includes a barrier carried by at least one of a first folding portion or a second folding portion of the computing device, the first folding portion rotatable relative to the second folding portion, and an actuator to move the barrier in response to a rotation between the first and second folding portions to reduce a flow of air into the foldable computing device.

### FIELD OF THE DISCLOSURE

This disclosure relates generally to computing devices and, more particularly, to methods and apparatus to control airflow in foldable computing devices.

### BACKGROUND

Lift/drop down hinges are implemented in known foldable computing devices for ergonomic considerations (e.g., keyboard use/accessibility), as well as performance. In such implementations, a base (e.g., a keyboard base, a chassis base) of a foldable computing device is rotatably coupled to a display. The base moves up relative to a surface (e.g. a table surface) when the foldable computing device is unfolded and/or the display of the foldable computing device is raised and/or rotated away from the base.

### BRIEF DESCRIPTION OF THE DRAWINGS

FIG. 1 depicts an example computing device constructed in accordance with teachings of this disclosure.

FIG. 2 depicts air flow patterns of the example computing device of FIG. 1.

FIGS. 3A and 3B depict an example deployable barrier system in accordance with teachings of this disclosure.

FIGS. 4A and 4B are side views of another example deployable barrier system.

FIG. 5 depicts another example barrier deployment system in accordance with teachings of this disclosure.

FIGS. 6A-6D depict yet another example barrier deployment system in accordance with teachings of this disclosure.

FIG. 7 is a flowchart representative of an example method to implement examples disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Methods and apparatus to control airflow in foldable computing devices are disclosed. Typically, a foldable computing device includes a base (e.g., a housing for a keyboard) and a display (e.g., a screen carried by a housing) which are pivotably coupled by a hinge. For example, a foldable computing device with a lift/drop down hinge are structured to contact a surface supporting the computing device to cause the base to move away from the surface supporting the foldable computing device as the display is rotated away from the base. The lifting of the base enables air to flow towards an inlet of the base to thereby enable improved thermal performance. Specifically, cool air from the environment passes into the base through the inlet to cool components of the computing device. However, based on a resultant flow pattern when lifting the base caused by a gap between the display and the base, exhaust air from the base can be caused to impinge on the display and flow back down towards an inlet of the base such that the heated air becomes recirculated into the inlet due to the aforementioned gap between the display and the base. In other words, such a gap can allow heated outlet air to enter an inlet (e.g., a fan inlet), thereby heating air what would otherwise cool electronic devices of the base.

Examples disclosed herein can improve a thermal performance of a foldable computing device with first and second folding portions that are rotatably coupled together at a hinge (e.g., a hinge assembly, a hinge portion, a hinge region, a pivot, etc.). Examples disclosed herein control (e.g., prevent) heated air from recirculating into the foldable computing device by utilizing a movable barrier. Such a barrier moves or is deployed and/or extended outward from a surface of a first folding portion of the foldable computing device. According to some examples disclosed herein, the barrier is deployed via an actuator (e.g., a mechanical actuator a movable body, a pivotable body, a translatable body, etc.), which may be separate from or integral with the barrier. In particular, displacement (e.g., rotational displacement) of the actuator can cause the barrier to extend away from an outer surface of the computing device, the first folding portion and/or the second folding portion as a result of movement (e.g., rotational movement) of the first folding portion with respect to the second folding portion. According to some examples disclosed herein, a rotational displacement between the first and second folding portions exceeding a threshold degree of rotational displacement enables and/or causes the barrier to extend past an external surface of the foldable computing device.

In some examples, the actuator includes a cam. In some such examples, the cam is rotationally displaced due to movement of the first folding portion, the second folding portion and/or the hinge. In turn, the cam causes displacement of the barrier and/or enables release/deployment of the barrier. Additionally or alternatively, the actuator is spring-loaded. For example, movement of the first folding portion with respect to the second folding portion (and vice-versa) can cause a release latch s (e.g., a lock) to enable the spring-loaded actuator to deploy and contact the surface supporting the foldable computing device. In some examples, the barrier is implemented as a wall. In some such examples, the barrier can span approximately 60%-100% (e.g., at least 90%) of an overall width of the foldable computing device. Additionally or alternatively, the barrier can include an elastic material that may be pressed and/or compressed against the surface supporting the foldable computing device.

As used herein, the term “foldable computing device” refers to a computing device that has folding portions that can fold relative to one another. Accordingly, as used herein, the term “foldable computing device” can refer to a device in which one of the folding portions includes a display or, alternatively, multiple folding portions that include a respective display (e.g., a foldable display computing device, etc.).

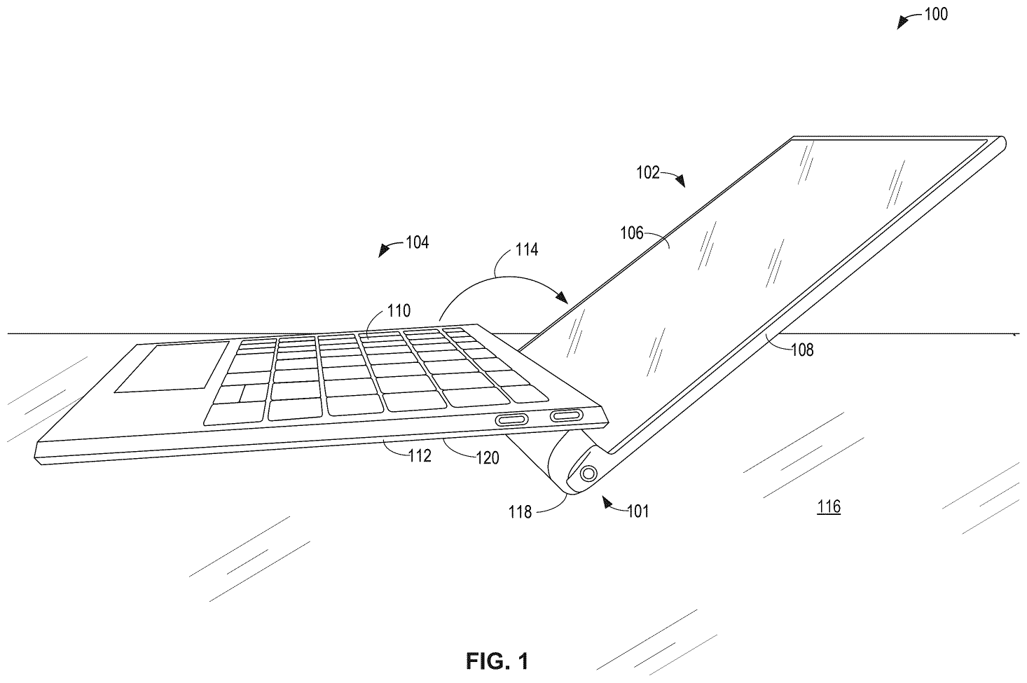

FIG. 1 depicts an example computing device 100 in which examples disclosed herein can be implemented. The computing device 100 of the illustrated example includes a hinge 101 that rotationally couples a first folding portion (e.g., a lid) 102 to a second folding portion 104. In this example, the first folding portion 102 includes a display 106 that is supported by a display chassis (e.g., a housing) 108. Further, the example second folding portion 104 includes an input device (e.g., a keyboard, a trackball, etc.) 110 supported by a base (e.g., a chassis or housing) 112. In this example, the computing device 100 is implemented as a laptop computer with a display that foldable relative to a base. However, examples disclosed herein can be implemented with any other appropriate type of computing device including, but not limited to, a mobile phone, a tablet, an electronic reader, a gaming device, a portable computing/gaming device, a portable device with a foldable display, etc.

To cause the display 106 to be positioned and/or oriented in a relatively upright position (e.g., a viewing position for a user), the first folding portion 102 is rotated away from the second folding portion 104, as generally indicated by an arrow 114. In the illustrated example of FIG. 1, the computing device 100 is supported by a surface 116, and a spatial arrangement of the hinge 101 with respect to the base 112 causes an air gap under the base 112 to be defined when the display 106 is positioned and/or oriented for viewing. More specifically, a rotational and/or angular displacement of the first folding portion 102 relative to the second folding portion 104 causes a body (e.g., a cam, a protrusion body, etc.) 118 of the hinge 101 to contact the surface 116 and, in turn, lift a lower surface 120 of the base 112 away from the aforementioned surface 116. In other words, based on the ergo-lift design, the bottom surface 120 sits above the surface 116 to define an air gap therebetween. In known implementations, this air gap can cause heated air to recirculate into an inlet of the computing device 100, thereby further heating internal components thereof and/or impeding cooling of the same. Further, overheating of the base 112 can cause a user to experience a relatively large degree of heat proximate their fingertips, which can be adverse from a user experience perspective.

Examples disclosed herein can effectively control distribution of airflow resulting from gaps at the hinge 101, as well as gaps underneath the aforementioned lower surface 120. According to some examples disclosed herein, rotating the first folding portion 102 relative to the second folding portion 104 with a rotational displacement therebetween exceeding a rotational angle threshold causes a barrier (e.g., a wall barrier, an elastic barrier, a flap, etc.) to deploy and/or extend away from the base 112 of the second folding portion 104. In some examples, a cam, linkage, gearing or other mechanism is utilized to deploy and/or displace the aforementioned barrier. Such a barrier can block or otherwise isolate heater air, as illustrated below.

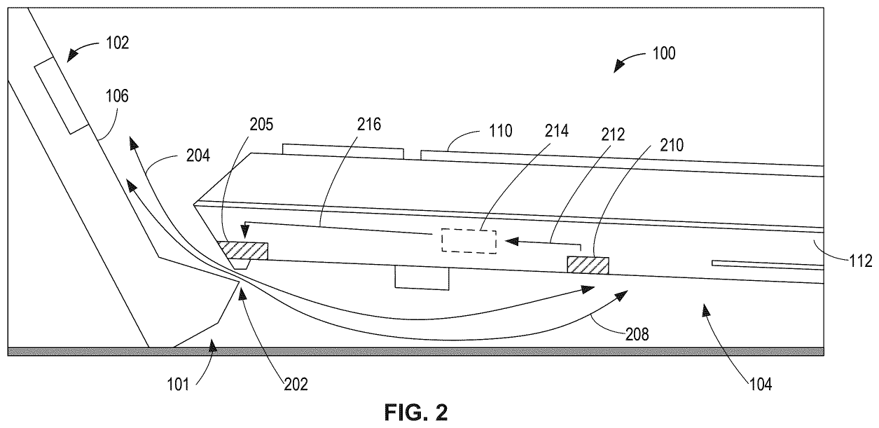

FIG. 2 depicts air flow patterns of the example computing device 100 of FIGS. 1A and 1B. In the illustrated example of FIG. 2, the first folding portion 102 is shown angled relative to the second folding portion 104 in an orientation corresponding to an operational configuration of the computing device 100 where the user operates the keyboard 110. In the illustrated view of FIG. 2, a gap 202 defined between contours of the hinge 101 and the base 112 results in air flow moving in directions depicted by arrows 204, 208. Accordingly, the arrows 204 correspond to air that is blown toward the display 106 of the first folding portion 102 from an exhaust 205 while arrows 208 correspond to heated air that is blown back under (and possibly into) an inlet 210 of the base 112 of the second folding portion 104. The heated air that enters the base 112 can cause an internal volume of the base 112, as generally indicated by an arrow 212, to experience a significant increase in heat of internal components 214 prior to the air exiting via the aforementioned exhaust 205 in a direction generally indicated by an arrow 216. In other words, air movement corresponding to the arrows 208 can result in unwanted (e.g., excessive) heating of the computing device 100 and, thus, potential reduced performance and cause battery depletion due to increased use of computing cooling devices to counteract the heating of the internal components 214 caused by the air movements along directions indicated by the arrows 208. In the illustrated view of FIG. 2, the air movement indicated by the arrows 204, 208 corresponds to heated air exiting the computing device 100 subsequent to cooling of heat generating components therein. As will be discussed in greater detail below, examples disclosed herein can advantageously control and/or isolate airflow with respect to the computing device 100 by preventing recirculation as well as unintended flow directed toward a user.

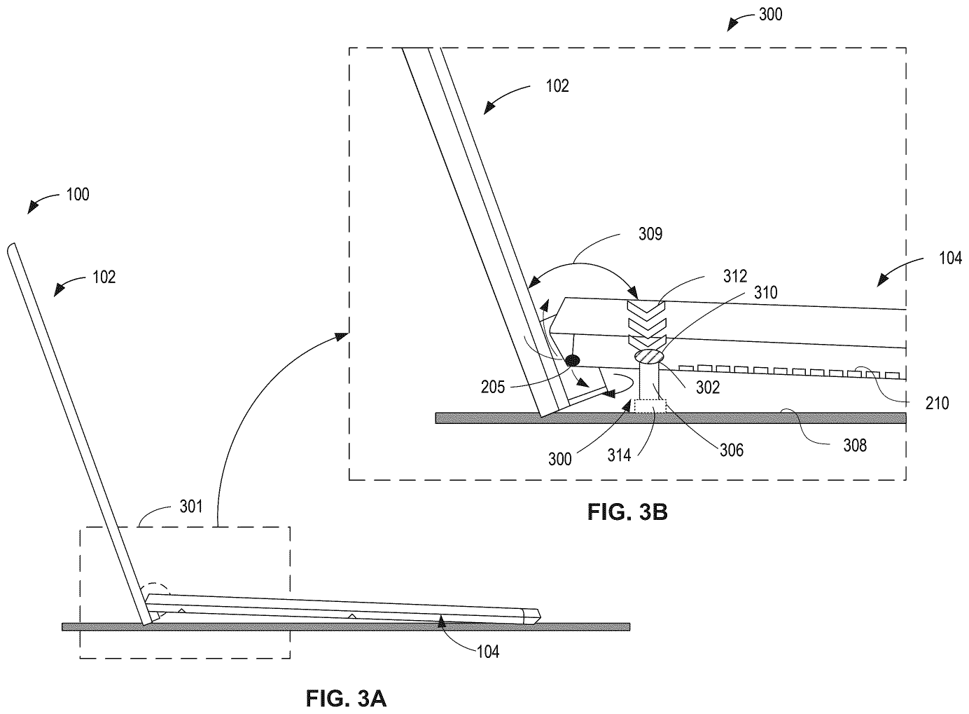

FIGS. 3A and 3B depict an example deployable barrier system 300 in accordance with teachings of this disclosure. Turning to FIG. 3A, the computing device 100 is shown with the first display portion 102 angled from the second display portion 104. A region 301 depicts an area of the computing device 100 in which the example deployable barrier system 300 is implemented and/or utilized.

FIG. 3B is a detailed view of the region 301 shown in FIG. 3A. In the illustrated example of FIG. 3B, the example deployable barrier system 300 includes an actuator (e.g., a mechanical actuator a movable body, a pivotable body, a translatable body, etc.) 302 operatively coupled to and/or including a barrier (e.g., a deployable barrier) 306, which is shown in a deployed state. The barrier 306 prevents heated air exiting from the exhaust 205 of the computing device 100 from re-entering the inlet 205 of the computing device 100. In this example, the deployable barrier 306 can move relative to the base 112 of the second folding portion 104.

According to the illustrated example of FIG. 3B, to deploy the barrier 306, the barrier 306 is extended and/or displaced downward (in the view of FIG. 3B) from the base 112. In this example, the actuator 302, which may or may not be integral with the deployable barrier 306, moves the barrier 306 toward a surface 308 supporting the computing device 100. In this particular example, a rotational displacement of the first folding portion 102 relative to the second folding portion 104, as indicated by a double arrow 309, exceeding a threshold angle (e.g., a threshold angular offset) causes the actuator 302 to displace the barrier 306 away from the base 112 (e.g., out of the computing device 100, further out of the computing device 100), as generally depicted by arrow heads 312. In this particular example, the actuator 302 and/or the barrier 306 includes geometry that defines a cam (e.g., a cam profile, an eccentric cam profile, etc.) 310. According to some examples disclosed herein, rotation (e.g., angular/rotational displacement) of the first folding portion 102 with respect to the second folding portion 104 translates to resultant rotation of the aforementioned cam 310, thereby pushing, extending and/or unfolding the barrier 306 toward the surface 308. The example barrier 306 can be deployed to contact (e.g., to be pushed against) or not contact the surface 308 (e.g., extend to be proximate the surface 308). In other examples, the actuator 302 defines and/or includes a linkage or at least one gear.

According to some examples disclosed herein, the barrier 306 is at least partially composed of an elastic material that is pressed and/or compressed against a supporting surface of the computing device 100. In some such examples, the elastic material can include, but is not limited to, an elastomer, a rubber compound, etc. Additionally or alternatively, the barrier 306 includes a foot 314, which may include an elastic material (e.g., rubber). The example foot 314 may have a larger footprint than the barrier 306, for example.

In some examples, a width of the barrier 306 spans 50%-100% (e.g., 90%) of a lateral width (e.g., an overall lateral width) of the computing device 100 and/or the base 112. In some examples, the barrier 306 is at least partially folded and/or compressed when stored in the base 112 and/or in an undeployed state. In some examples, the barrier 306 acts as a stand (e.g., when deployed from the base 112, in at least one rotational displacement between the first folding portion 102 and the second folding portion 104). In other words, in some examples, the barrier 306 can at least partially support a weight of the computing device 100. In some other examples, the barrier 306 does not contact the surface 308 supporting the computing device 100 when the barrier 306 is fully deployed/extended from the base 112.

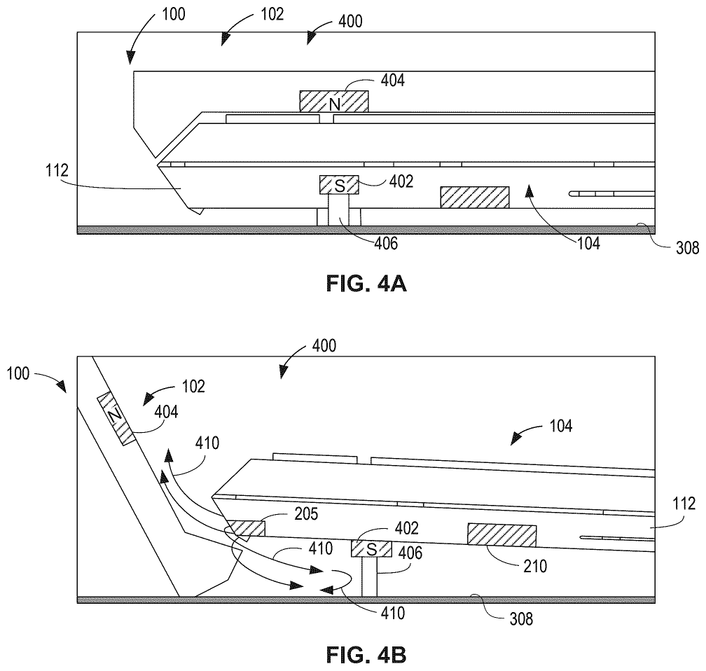

FIGS. 4A and 4B are side views of an example deployable barrier system 400 that utilizes magnets and/or magnetic forces in combination with a spring device/mechanism. Turning to FIG. 4A, the computing device 100 is depicted with the first folding portion 102 oriented in a closed position with respect to the second folding portion 104. In this example, a first magnet 402 of the second folding portion 104 and a second magnet 404 of the first folding portion 102 are shown. According to some examples disclosed herein, the first magnet 402 is operatively coupled to a barrier 406 that extends away from the base 112 to be proximate to or contact the surface 308 when a rotational displacement between the first folding portion 102 and the second folding portion 104 exceeds a threshold angle. In the illustrated example of FIG. 4A, the first magnet 402 and the second magnet 404 experience an attractive force therebetween and, as a result, the barrier 406 is held and/or pulled upward (in the view of FIG. 4A). In this example, the first magnet 402 and the second magnet 404 are permanent magnets. In other examples, at least one electromagnet is utilized. In some examples, the first magnet 402 is positioned at a distal end of the barrier 406 (e.g., at a foot of the barrier 406).

Turning to FIG. 4B, the example computing device 100 is shown with the first display portion 102 rotated further away from the second folding portion 104 than shown in the example of FIG. 4A. In the illustrated example of FIG. 4B, the example barrier 406 is depicted extended further away from the base 112 than depicted in FIG. 4A. In particular, based on a relative rotational displacement between the first folding portion 102 and the second folding portion 104, the second magnet 404 has been displaced at a distance from the first magnet 402, such that a magnetic attraction therebetween has been significantly reduced, thereby enabling the barrier 406 to move toward a surface supporting the computing device 100. According to some examples disclosed herein, the barrier 406 and/or the first magnet 402 is spring-loaded to push the barrier 406 toward the surface 308. In the illustrated example, the barrier 406 has a different length because the barrier 406 is compressible and/or foldable. In some examples, the second magnet 404 imparts an attractive force to the barrier 406 (e.g., at least a portion of the barrier 406 includes and/or supports a metal, the barrier 406 is integral with the first magnet 402, etc.).

As result of the barrier 406 being displaced away from the base 112, arrows 410 indicate an exhaust flow pattern from the base 112 that is advantageously isolated from the inlet 210 of the second folding portion 104 and, thus, heated air exiting the computing device 100 from the outlet 205 is prevented from re-entering the inlet 210. Based on the isolation of exhaust flow, components of the computing device 100 are maintained at a relatively low temperature.

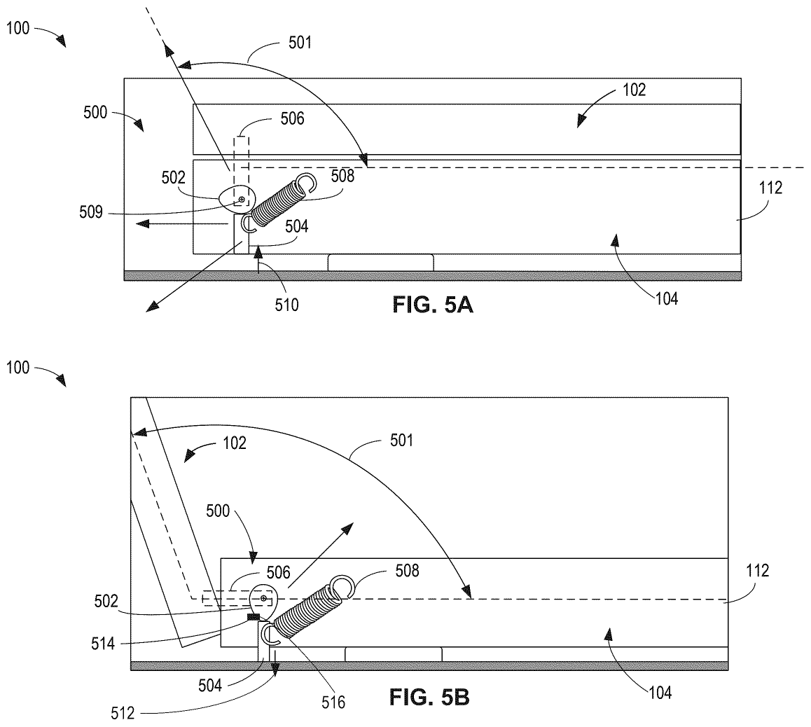

FIGS. 5A and 5B depict an example barrier deployment system 500 that is constructed in accordance with examples disclosed herein. In the illustrated example of FIG. 5A, the computing device 100 is depicted with the first folding portion 102 and the second folding portion 104 angled from another, but having a rotational displacement therebetween that is less than a threshold angle, which is generally denoted by a double arrow 501, that causes the barrier deployment system 500 to deploy. The barrier deployment system 500 of the illustrated example includes an actuator 502, which is implemented as a rotatable cam in this example, a barrier 504, a hinge body 506 and a spring 508. The example hinge body 506 can be implemented as a linkage, a lever, a strap, a chain, a movable bar, etc.

In the illustrated view of FIG. 5A, the barrier 504 is depicted positioned within the base 112 of the second folding portion 104, as generally indicated by an arrow 510. To cause at least a portion of the barrier 504 to displace and/or extend away from the base 112 and toward a surface supporting the computing device 100 (as generally indicated by a double arrow 510), the first folding portion 102 is rotationally moved and/or displaced with respect to the second folding portion 104 which, in turn, causes movement of the hinge body 506 along with the barrier 504. In particular, the movement (e.g., translational movement, pivoting movement, etc.) of the hinge body 506 causes rotation of the actuator 502. The example actuator 502 includes an eccentric shape relative to its pivot (e.g., an axis of rotation) 509. Because of its eccentric shape, the actuator 502 moves the barrier 504 out of and/or relative to the base 112. In this example, the barrier 504 is fully disposed within the base 112 at certain relative rotational displacement(s) (e.g., a rotational displacement range) between the first folding portion 102 and the second folding portion 104. In other examples, the barrier 504 at least partially extends out of the base 112 at all rotational displacements between the first folding portion 102 and the second folding portion 104, and a degree to which the barrier 504 extends out of the base 112 varies and/or is changed based on a degree of rotational displacement between the first folding portion 102 and the second folding portion 104 and, thus, the rotation of the cam 502.

FIG. 5B depicts the barrier 504 displaced away from the base 112, as generally indicated by an arrow 512. In this example, the computing device 100 with the barrier 504 extended out and away from the base 112 of the second folding portion 104. In particular, the first folding portion 102 is at a rotational displacement from the second folding portion 104 that exceeds the threshold rotational displacement generally indicated by the double arrow 501, thereby causing the hinge body 506 to rotate and/or translate and, in turn, rotate the actuator 502. Accordingly, the rotation of the actuator 502 causes the barrier 604 to be displaced relative to the base 112. In this particular example, a rotational motion of the actuator 502 can counteract a force (e.g., a tensile force) of the spring 508.

In some examples, the spring 508 pushes against the barrier 504 to urge and/or compress the barrier 504 against a surface supporting the computing device 100. In some such examples, the barrier 504 can be flexible and/or exhibit elastic behavior. In some examples, a magnet is utilized to counteract a force of the spring 508. In some such examples, the magnet can provide an attractive force to the barrier 504 and/or the actuator 502.

According to some examples disclosed herein, a lock 514 is implemented to restrict and/or prevent motion of the movable body 502, the barrier 504 and/or the hinge body 506. According to some examples disclosed herein, the lock 514 is spring-loaded. Additionally or alternatively, a portion (e.g., a movable portion, a spring-loaded portion) of the lock 514 is received by an indent, a slot and/or aperture 516 of the movable body 502, the barrier 504 or the hinge body 506. In some examples, the lock 514 is released, unlocked and/or controlled based on and/or in response to movement of the hinge body 506.

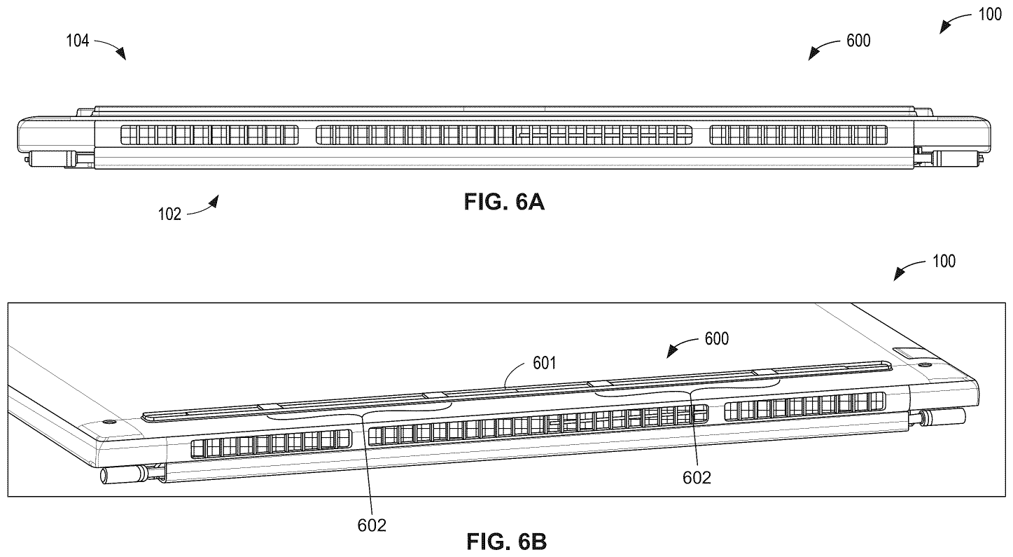

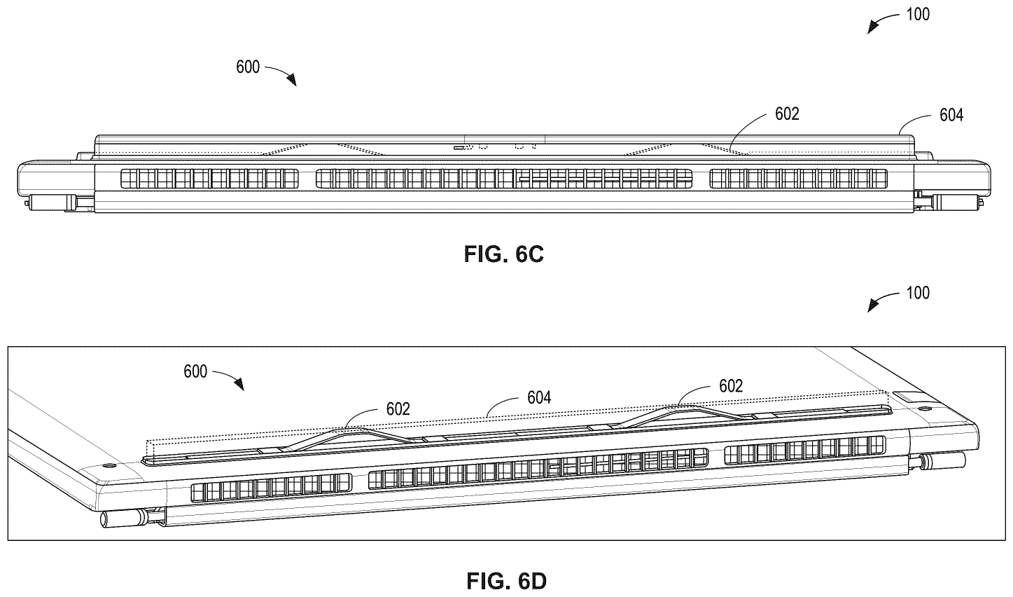

FIGS. 6A-6D depict yet another example barrier deployment system 600. Turning to FIG. 6A, a top view of the computing device 100 is shown with the first folding portion 102 folded against and/or generally moved toward the second folding portion 104. In this example, the barrier deployment system 600 is shown positioned on the second folding portion 104. Additionally or alternatively, the example barrier deployment system 600 is positioned on the first folding portion 102.

FIG. 6B depicts the example barrier deployment mechanism 600 in a perspective view. The aforementioned example barrier deployment system 600 includes a spine 601 with actuators (e.g., barbs, arms, etc.) 602 spaced at intervals of the aforementioned spine 601. In this particular example, two of the actuators 602 are utilized (as can be seen in FIGS. 6C and 6D). However, any other appropriate number of the actuators 602 can be implemented instead (e.g., one, three, four five, six, seven, eight, nine, ten, . . . twenty, etc.).

FIG. 6C depicts the example barrier deployment system 600 with a barrier 604 deployed. In particular, the aforementioned actuators 602 are deployed and/or displaced. In this example, the actuators 602 position and/or support the barrier 604. Any of the examples disclosed herein (or any other appropriate deployment device/apparatus) can be implemented to deploy and/or displace the actuators 602 and/or the barrier 604. In some examples, the barrier 604 includes and/or defines a fabric, a membrane (e.g., an elastic membrane, a membrane wall, a fabric membrane, etc.), a sheet, etc., which can be foldable and/or storable. In some examples, the barrier 604 is an elastic sponge or flexible fabric compressed and hidden inside a rubber feet slot. According to some examples disclosed herein, the actuators 602 can act as supports (e.g., masts, spines, etc.) that at least partially span the barrier 604. In some examples, the actuators 602 include at least a metal portion and repel the barrier 604 in response to a magnet placed on the first folding portion 102 being rotated closer to the second folding portion 104.

FIG. 6D depicts the deployed example barrier deployment system 600 in perspective view. In the illustrated example of FIG. 6D, the actuators 602 are shown deployed along with the barrier 604, which is partially hidden in the view of FIG. 6D for enhanced clarity. According to some examples disclosed herein, the barrier 604 is folded and/or compressed when the actuators 602 are in their stowed position (as opposed to being deployed).

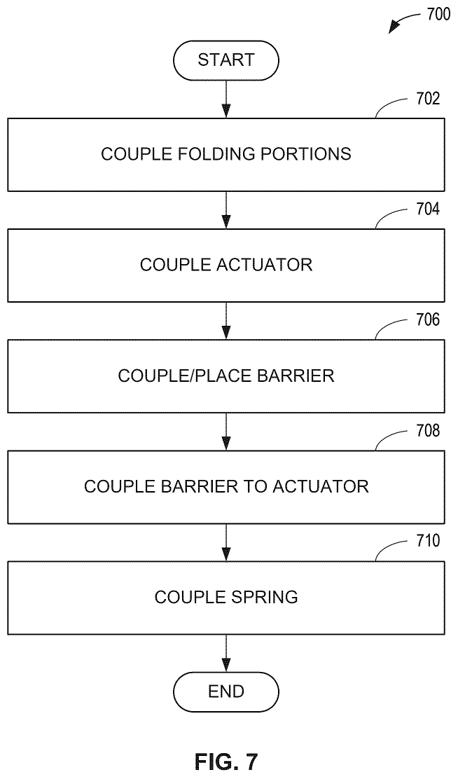

FIG. 7 is a flowchart representative of an example method 700 to produce and/or implement examples disclosed herein. The example method 700 can, alternatively, be utilized to retrofit and/or modify existing computing devices, for example.

At block 702, according to some examples disclosed herein, the first folding portion 102 and the second folding portion 104 are rotationally/operatively coupled to one another at or by the hinge 101. In some examples, a hinge body of the hinge is placed to translate rotational displacement between the first folding portion 102 and the second folding portion 104.

At block 704, an actuator (e.g., the actuator 302, the actuator 402, the actuator 502, the actuator 602) is operationally coupled to a hinge (e.g., the hinge 101) and/or a hinge body (e.g., the hinge body 506). In some examples, the actuator is integral with the hinge body.

At block 706, a barrier (e.g., the barrier 306, the barrier 406, the barrier 504, the barrier 604,) is operatively coupled, placed and/or aligned. According to some examples disclosed herein, the barrier is placed in the base 112 and aligned relative to the base 112 and/or the hinge. In some examples, the barrier is integral with the actuator. In some such examples, the actuator includes geometry corresponding to features and/or geometric/kinematic characteristics of a cam.

At block 708, in some examples, the barrier is operatively coupled to the actuator. In some other examples, the barrier is integral with the actuator.

According to some examples disclosed herein, at block 710, a spring or other appropriate force-applying device is operatively coupled to the actuator and/or the barrier, and the process ends. In some particular examples, the spring is implemented to urge the barrier to contact a surface supporting the computing device 100 (e.g., by contact thereto and/or being operatively coupled to the actuator).

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

As used in this patent, stating that any part is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

Example methods, apparatus, systems, and articles of manufacture to enable improved thermal performance of computing devices are disclosed herein. Further examples and combinations thereof include the following:

Example 1 includes an apparatus for use with a foldable computing device, the apparatus comprising a barrier carried by at least one of a first folding portion or a second folding portion of the computing device, the first folding portion rotatable relative to the second folding portion, and an actuator to move the barrier in response to a rotation between the first and second folding portions to reduce a flow of air into the foldable computing device.

Example 2 includes the apparatus as defined in example 1, wherein the actuator includes a cam to vary a displacement of the barrier with respect to at least one of the first folding portion or the second folding portion.

Example 3 includes the apparatus as defined in example 2, further including a linkage to translate the rotation between the first folding portion with respect to the second folding portion to rotational motion of the cam.

Example 4 includes the apparatus as defined in any of examples 1 to 3, wherein the actuator includes a first magnet, and a second magnet is moved by the rotation between the first and second folding portions to change a degree of attraction between the first and second magnets to displace the actuator.

Example 5 includes the apparatus as defined in any of examples 1 to 4, wherein the barrier includes an elastic material to be compressed against a surface supporting the computing device.

Example 6 includes the apparatus as defined in any of examples 1 to 5, wherein the barrier defines a stand of the computing device in at least one rotational displacement between the first and second folding portions.

Example 7 includes the apparatus as defined in any of examples 1 to 6, wherein the actuator includes an arm, and the barrier includes a wall that is at least one of expanded or unfolded in response to displacement of the arm.

Example 8 includes a computing device comprising a lid, a base, an inlet in at least the lid or the base, a hinge to couple the lid and the base, and a barrier movable based on a rotation of at least one of the lid or the base to direct air flow away from the inlet.

Example 9 includes the computing device as defined in example 8, further including at least one of a linkage or a cam to translate rotational motion of at least one of the lid or the base to translational motion of the barrier.

Example 10 includes the computing device as defined in any of examples 8 or 9, further including a spring to urge the barrier against a surface supporting the computing device.

Example 11 includes the computing device as defined in example 10, further including a magnet to provide an attractive force to the barrier or an actuator operatively coupled to the barrier to prevent the spring from urging the barrier when the rotation of at least one of the lid or the base is less than a rotational angle threshold.

Example 12 includes the computing device as defined in any of examples 8 to 11, further including a cam operatively coupled to the barrier, the cam to be rotated based on the rotation of at least one of the lid or the base.

Example 13 includes the computing device as defined in any of examples 8 to 12, further including a first magnet operatively coupled to the barrier, and a second magnet that is moved based on the rotation of at least one of the lid or the base, wherein a degree of attraction between the first and second magnets is to change a degree of movement of the barrier.

Example 14 includes the computing device as defined in example 13, wherein the barrier is urged by a spring that counteracts an attractive force between the first and second magnets.

Example 15 includes the computing device as defined in any of examples 8 to 14, wherein the barrier spans a distance of at least 90% of a width of the computing device.

Example 16 includes the computing device as defined in any of examples 8 to 15, wherein the barrier is between an exhaust outlet and the inlet.

Example 17 includes the computing device as defined in any of examples 8 to 16, wherein the barrier includes a fabric or membrane that is supported by an actuator that includes arms to unfold the fabric or membrane.

Example 18 includes a method comprising placing a barrier onto at least one of a first folding portion or a second folding portion of a computing device, the first folding portion rotatable to the second folding portion, and operatively coupling an actuator to the barrier the actuator to move the barrier in response to a rotation between the first and second folding portions.

Example 19 includes the method as defined in example 18, further including operatively coupling a spring to at least one of the actuator or the barrier.

Example 20 includes the method as defined in any of examples 18 or 19, further including operatively coupling a first magnet to the first folding portion, and operatively coupling a second magnet to the second folding portion, the first and second magnets having an attractive force therebetween to move the barrier in response to the rotation between the first and second folding portions.

From the foregoing, it will be appreciated that example systems, apparatus, articles of manufacture, and methods have been disclosed that enable effective cooling of computing devices. Examples disclosed herein can improve a user experience by preventing a significant degree of heating on portions and/or regions of computing devices. Examples disclosed herein can improve heat removal performance by reducing (e.g., preventing) recirculation of heat/air back into computing devices. Such reductions can improve heat removal significantly (e.g., by approximately 20% or more, for example).

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus for use with a foldable computing device, the apparatus comprising:
a barrier carried by at least one of a first folding portion or a second folding portion of the computing device, the first folding portion rotatable relative to the second folding portion; and
an actuator to move the barrier in response to a rotation between the first and second folding portions to reduce a flow of air into the foldable computing device.

2. The apparatus as defined in claim 1, wherein the actuator includes a cam to vary a displacement of the barrier with respect to at least one of the first folding portion or the second folding portion.

3. The apparatus as defined in claim 2, further including a linkage to translate the rotation between the first folding portion with respect to the second folding portion to rotational motion of the cam.

4. The apparatus as defined in claim 1, wherein the actuator includes a first magnet, and a second magnet is moved by the rotation between the first and second folding portions to change a degree of attraction between the first and second magnets to displace the actuator.

5. The apparatus as defined in claim 1, wherein the barrier includes an elastic material to be compressed against a surface supporting the computing device.

6. The apparatus as defined in claim 1, wherein the barrier defines a stand of the computing device in at least one rotational displacement between the first and second folding portions.

7. The apparatus as defined in claim 1, wherein the actuator includes an arm, and the barrier includes a wall that is at least one of expanded or unfolded in response to displacement of the arm.

8. A computing device comprising:
a lid;
a base, an inlet in at least the lid or the base;
a hinge to couple the lid and the base; and
a barrier movable based on a rotation of at least one of the lid or the base to direct air flow away from the inlet.

9. The computing device as defined in claim 8, further including at least one of a linkage or a cam to translate rotational motion of at least one of the lid or the base to translational motion of the barrier.

10. The computing device as defined in claim 8, further including a spring to urge the barrier against a surface supporting the computing device.

11. The computing device as defined in claim 10, further including a magnet to provide an attractive force to the barrier or an actuator operatively coupled to the barrier to prevent the spring from urging the barrier when the rotation of at least one of the lid or the base is less than a rotational angle threshold.

12. The computing device as defined in claim 8, further including a cam operatively coupled to the barrier, the cam to be rotated based on the rotation of at least one of the lid or the base.

13. The computing device as defined in claim 8, further including:
a first magnet operatively coupled to the barrier; and
a second magnet that is moved based on the rotation of at least one of the lid or the base, wherein a degree of attraction between the first and second magnets is to change a degree of movement of the barrier.

14. The computing device as defined in claim 13, wherein the barrier is urged by a spring that counteracts an attractive force between the first and second magnets.

15. The computing device as defined in claim 8, wherein the barrier spans a distance of at least 90% of a width of the computing device.

16. The computing device as defined in claim 8, wherein the barrier is between an exhaust outlet and the inlet.

17. The computing device as defined in claim 8, wherein the barrier includes a fabric or membrane that is supported by an actuator that includes arms to unfold the fabric or membrane.

18. A method comprising:
placing a barrier onto at least one of a first folding portion or a second folding portion of a computing device, the first folding portion rotatable to the second folding portion; and
operatively coupling an actuator to the barrier the actuator to move the barrier in response to a rotation between the first and second folding portions.

19. The method as defined in claim 18, further including operatively coupling a spring to at least one of the actuator or the barrier.

20. The method as defined in claim 18, further including:
operatively coupling a first magnet to the first folding portion; and
operatively coupling a second magnet to the second folding portion, the first and second magnets having an attractive force therebetween to move the barrier in response to the rotation between the first and second folding portions.
